(19) United States
(12) Patent Application Publication
(10) Pub. No.: US 2018/0193922 A1
(43) Pub. Date: Jul. 12, 2018

(54) TECHNIQUES FOR HYBRID ADDITIVE AND SUBSTRACTIVE MANUFACTURING

(71) Applicant: Voxel8, Inc., Somerville, MA (US)

(72) Inventors: Michael Austin Bell, Somerville, MA (US); Andrew Marschner, Somerville, MA (US); Robert Douglas Weeks, Welland (CA); Travis Alexander Busbee, Somerville, MA (US); Kyle Jackson Dumont, Arlington, MA (US); John Eugene Minardi, Somerville, MA (US)

(73) Assignee: Voxel8. Inc., Somerville, MA (US)

(21) Appl. No.: 15/405,263

(22) Filed: Jan. 12, 2017

(51) Int. Cl. B22F 7/00; B33Y 10/00; B33Y 80/00; B33Y 30/00; B33Y 50/02; B29C 67/00; B22F 3/105; B22F 3/10; H05K 3/00; H05K 3/12

(52) U.S. Cl. CPC B22F 7/008; B33Y 10/00; B33Y 80/00; B33Y 30/00; B33Y 50/02; B29K 2101/10; B22F 3/1055; B22F 3/1017; H05K 3/0014; H05K 3/0055; H05K 3/12; B29C 67/0051

(57) ABSTRACT

According to at least one aspect, a method of manufacturing a three-dimensional (3D) object comprising a plurality of materials is provided. The method comprises depositing a first material via additive manufacturing, removing at least some deposited material via subtractive manufacturing, and after removing the at least some deposited material, depositing a second material via additive manufacturing.

### BACKGROUND

Conventional additive manufacturing devices, such as three-dimensional (3D) printers, typically manufacture an object by successively forming a series of material layers in accordance with a model of the object to be manufactured. These layers may have a thickness between, for example, 10 micrometers (μm) and 1 millimeter (mm). Typically each layer is formed such that it adheres to one or more previously formed layers or a build surface upon which the object is built. Some 3D printers may successively form layers directly on top of each other such that the layers are parallel with each other. Other 3D printers may rotate the object between formation of layers to allow formation of a layer on a side of the object that is perpendicular to one or more previously formed layers. Example additive manufacturing techniques may include direct ink writing (DIW), stereolithography (SL), fused deposition modeling (FDM), laser sintering, laminated object manufacturing (LOM), material jetting, or combinations thereof.

### SUMMARY

According to at least one aspect, a method of manufacturing a three-dimensional (3D) object comprising a first material and a second material is provided. The method comprises depositing the first material in a first layer via additive manufacturing, removing at least some material in the first layer via subtractive manufacturing, and after removing the at least some material in the first layer, depositing the second material in the first layer via additive manufacturing.

In some embodiments, removing the at least some material in the first layer comprises facing the deposited first material in the first layer. In some embodiments, removing the at least some material in the first layer comprises forming at least one cavity in the deposited first material in the first layer. In some embodiments, depositing the second material in the first layer comprises depositing the second material into the at least one cavity.

In some embodiments, the method further comprises depositing the first material in a second layer that is on top of the first layer via additive manufacturing, removing at least some material in the second layer via subtractive manufacturing, and after removing the at least some material in the second layer, depositing the second material in the second layer via additive manufacturing. In some embodiments, the method further comprises depositing the second material in a second layer that is on top of the first layer via additive manufacturing, depositing the first material in the second layer via additive manufacturing, and after depositing the first and second materials in the second layer, removing at least some material in the second layer via subtractive manufacturing.

In some embodiments, the method further comprises curing the deposited first material in the first layer before removing the at least some material in the first layer. In some embodiments, curing the deposited first material comprises curing the deposited first material using at least one member selected from the group consisting of: ultraviolet (UV) light, infrared (IR) light, laser light, heat, and an electron beam.

In some embodiments, the method further comprises cleaning the deposited first material after removing the at least some material in the first layer. In some embodiments, additive manufacturing comprises at least one member selected from the group consisting of: direct ink writing (DIW), stereolithography (SL), fused deposition modeling (FDM), laser sintering, laminated object manufacturing (LOM), doctor blading, material spraying, and material jetting. In some embodiments, subtractive manufacturing comprises at least one member selected from the group consisting of: milling, drilling, cutting, etching, grinding, sanding, planing, and turning.

According to at least one aspect, a method of manufacturing a 3D object comprising a first material and a second material is provided. The method comprises depositing the first material in a first layer via additive manufacturing, depositing the second material in the first layer using additive manufacturing, and after depositing the first and second materials in the first layer, removing at least some material in the first layer via subtractive manufacturing.

In some embodiments, removing the at least some material in the first layer comprises removing at least some of the deposited first material and the deposited second material in the first layer. In some embodiments, removing the at least some material in the first layer comprises facing the deposited first material and the deposited second material in the first layer.

In some embodiments, the method further comprises depositing the second material in a second layer that is on top of the first layer via additive manufacturing, depositing the first material in the second layer via additive manufacturing, and after depositing the first and second materials in the second layer, removing at least some material in the second layer via subtractive manufacturing. In some embodiments, the method further comprises cleaning the deposited first and second materials after removing the at least some material in the first layer.

According to at least one aspect, a method of manufacturing a printed circuit board (PCB) is provided. The method comprising depositing a thermosetting matrix material in a layer via additive manufacturing, curing the thermosetting matrix material in the layer, removing at least some material in the layer via subtractive manufacturing, and after removing the at least some material in the layer, depositing a conductive material in the layer via additive manufacturing.

In some embodiments, depositing the thermosetting matrix material in the layer comprises depositing the thermosetting matrix material at least in part by direct ink writing or material spraying. In some embodiments, removing the at least some material in the layer comprises forming at least one channel in the deposited thermosetting matrix material. In some embodiments, depositing the conductive material in the layer comprises depositing the conductive material in the at least one channel.

According to at least one aspect, a manufacturing system is provided. The manufacturing system comprises a first material deposition tool configured to receive a compressed gas and deposit a first material using the received compressed gas, a gas control device configured to control a pressure of the compressed gas, a spindle configured to removably couple to the first material deposition tool, receive the compressed gas, and operate the first material deposition tool at least in part by providing the compressed gas to the first material deposition tool, a build platform disposed below the spindle, a gantry system coupled between the build platform and the spindle, the gantry system configured to move the spindle relative to the build platform in a plurality of directions, and a controller communicatively coupled to the gas control device and configured to set the pressure of the compressed gas to a first level to deposit the first material.

In some embodiments, the gas control device comprises a pressure regulator or a gas compressor. In some embodiments, the first material deposition tool is mounted to the spindle via a tool holder and the spindle is configured to operate the first material deposition tool at least in part by providing the compressed gas to the tool holder.

In some embodiments, the system further comprises a tool storage compartment configured to hold a plurality of tools each configured to removably couple to the spindle, the plurality of tools including the first material deposition tool and a tool changer configured to mount a selected tool from the plurality of tools in the tool storage compartment to the spindle. In some embodiments, the plurality of tools comprises a second material deposition tool configured to receive the compressed gas and deposit the second material using the received compressed gas. In some embodiments, the controller is communicatively coupled to the tool changer and is further configured to instruct the tool changer to mount the second material deposition tool to the spindle and set the pressure of the compressed gas to a second level that is different from the first level to deposit the second material. In some embodiments, the plurality of tool comprises a cutting tool configured to remove at least some of the deposited first material. In some embodiments, the spindle is configured to operate the cutting tool at least in part by rotating the cutting tool. In some embodiments, the cutting tool comprises a milling tool, a drilling tool, or a laser etching tool.

In some embodiments, the system further comprises an enclosure configured to enclose at least part of the build platform and the gantry system. In some embodiments, the enclosure comprises at least one window configured to block at least some UV light. In some embodiments, the at least one window is configured to block at least 95% of UV light.

In some embodiments, the plurality of directions comprises a first direction, a second direction that is perpendicular to the first direction, and a third direction that is perpendicular to the first direction and the second direction. In some embodiments, the gantry system is configured to move the build platform in the first direction and the second direction and move the spindle in the third direction.

According to at least one aspect, a manufacturing system is provided. The manufacturing system comprises a plurality of tools including a first material deposition tool configured to deposit a first material, a second material deposition tool configured to deposit a second material, and a cutting tool configured to remove at least some deposited material, a spindle configured to operate a tool from the plurality of tools that is mounted to the spindle, a tool changer configured to change the tool mounted to the spindle, a build platform disposed below the spindle, and a gantry system coupled between the build platform and the spindle, the gantry system configured to move the spindle relative to the build platform in a plurality of directions.

In some embodiments, the first material deposition tool comprises a reservoir to store the first material and a nozzle coupled to the reservoir to deposit the first material. In some embodiments, the first material deposition tool comprises a motor configured to deposit the first material from the reservoir and the spindle is configured to operate the first material deposition tool at least in part by providing power to the motor via a slip ring assembly.

In some embodiments, the system comprises a material storage compartment coupled to the spindle and configured to store the first material. In some embodiments, the first material deposition tool comprises a port configured to receive the first material and the spindle is configured to operate the first material deposition tool at least in part by providing the first material to the port.

According to at least one aspect, a manufacturing system is provided. The manufacturing system comprises a plurality of tools including a first material deposition tool configured to deposit a first material, a second material deposition tool configured to deposit a second material, and a cutting tool configured to remove at least some deposited material and a spindle configured to operate a tool from the plurality of tools that is mounted to the spindle where the manufacturing system is configured to create a 3D object comprising a plurality of layers and the manufacturing system is configured to create one or more layers of the plurality of layers at least in part by depositing the first material in the one or more layers using the first material deposition tool, depositing the second material in the one or more layers using the second material deposition tool, and removing at least some material from the one or more layers using the cutting tool.

The foregoing is a non-limiting summary of the invention, which is defined by the attached claims.

### BRIEF DESCRIPTION OF THE DRAWINGS

Various aspects and embodiments will be described with reference to the following figures. It should be appreciated that the figures are not necessarily drawn to scale. In the drawings, each identical or nearly identical component that is illustrated in various figures is represented by a like numeral. For purposes of clarity, not every component may be labeled in every drawing.

FIGS. 1A-1B each show an example state diagram of a layer at various points during a hybrid additive and subtractive manufacturing process, according to some embodiments of the technology described herein;

FIG. 2 shows an example machine for additive and subtractive manufacturing, according to some embodiments of the technology described herein;

FIG. 3 shows the example machine of FIG. 2 in an enclosure, according to some embodiments of the technology described herein;

FIGS. 4A-4B show an example tool changer, according to some embodiments of the technology described herein;

FIGS. 5A-5B each show an example material deposition tool, according to some embodiments of the technology described herein;

FIG. 6 shows an example squeegee tool, according to some embodiments of the technology described herein;

FIG. 7 shows an example curing tool, according to some embodiments of the technology described herein;

FIG. 8 shows an example cleaning tool, according to some embodiments of the technology described herein; and

FIGS. 9-11 each show an example method of manufacturing at least a portion of a layer of an object, according to some embodiments of the technology described herein.

### DETAILED DESCRIPTION

As discussed above, many additive manufacturing techniques form objects by successively forming a series of material layers that adhere to a build surface or one or more previously formed layers. In direct ink writing (DIW), for example, each of the layers may be formed by extruding a material (e.g., an ink) through a nozzle as the position of the nozzle is controlled. The size of the nozzle may determine the narrowest width that material may be deposited in a given layer. For example, a circular nozzle with a diameter of 0.5 millimeters (mm) may be unable to create a feature in a layer with a width that is smaller than 0.5 mm. Thereby, nozzles sizes are typically relatively small (e.g., 0.4 mm or 0.35 mm) to allow the additive manufacturing devices to create small features in a given layer.

The inventors have appreciated that objects comprising multiple materials typically include small features that constrain the nozzle size that may be employed for one or both of the materials. Thereby, manufacturing such objects with small nozzles may take multiple days. For example, manufacturing a larger area (e.g., a surface area of 480 square inches) multi-layer printed circuit board (PCB) with both a conductive material in thin strips to form conductive channels and a non-conductive structural material between the conductive channels may take between four and five days to manufacture.

The inventors have conceived and developed new hybrid additive and subtractive manufacturing techniques to manufacture objects with multiple materials faster than conventional additive manufacturing techniques. In some embodiments, these hybrid additive and subtractive manufacturing techniques coarsely deposit a first material in a layer that does not comply with the specification for the layer and subsequently bring the first material in the layer closer to compliance (or in complete compliance) with the specification using various cutting tools. Once the first material is brought into compliance (or substantial compliance) with the specification for the layer, a second material may be deposited in the layer. This process of coarsely depositing a material and subsequently removing some of the deposited material may allow the use of fast deposition techniques. Thereby, the time required to complete a layer (and an object comprising multiple layers) may be substantially reduced. For example, the time to manufacture a larger area multi-layer PCB comprising two or more different materials may be reduced from four or five days to less than ten hours.

Accordingly, some aspects of the present disclosure relate to a method of manufacturing an object (e.g., a PCB) comprising a plurality of materials including a first material and a second material. Each of the plurality of materials may be distinguishable from the other materials in the plurality of materials (e.g., the first material may be distinguishable from the second material). For example, the first material and the second material may have different compositions (e.g., the first material may have a different chemical formula than the second material) and/or different properties (e.g., the first material may have a different conductivity than the second material). In some cases, the second material may have a conductivity that is larger than the conductivity of the first material (e.g., at least 2 times larger, at least 5 times larger, at least 10 times larger, at least 25 times larger, at least 50 times larger, and/or at least 100 times larger). For example, the first material may comprise a polymer and the second material may comprise a metal.

The method of manufacturing may include depositing the first material in a layer via additive manufacturing. Any of a variety of additive manufacturing techniques may be employed such as DIW, stereolithography (SL), fused deposition modeling (FDM), laminated object manufacturing (LOM), laser sintering, doctor blading, material spraying (e.g., AEROSOL JET spraying, thermal spraying, cold spraying), and material jetting. The first material may be coarsely deposited in the layer such that the deposited material fails to meet the specification for the layer. For example, the coarsely deposited material may omit one or more cavities for the second material to be deposited and/or have a thickness that is greater than the desired thickness for the layer.

After depositing the first material, some of the deposited first material in the layer may be removed via subtractive manufacturing. Any of a variety of subtractive manufacturing techniques may be employed such as milling, drilling, turning, grinding, sanding, and laser etching. Some of the first deposited material may be removed to bring the deposited first material closer to compliance (or in full compliance) with the specification for the layer. For example, a top surface of the first deposited material may be faced to even the surface and/or reduce a thickness of the first deposited material. Additionally (or alternatively), cavities may be formed for the subsequent deposition of another material in the layer.

After removing some of the deposited first material, the second material may be deposited in the layer via additive manufacturing. For example, the second material may be deposited into cavities formed in the deposited first material. The second material may be deposited using the same (or different) additive manufacturing technique that was employed to deposit the first material. For example, both the first and second material may be deposited by DIW. In another example, the first material may be deposited by FDM and the second material may be deposited by DIW.

It should be appreciated that various modifications may be made to the above described method of manufacturing without departing from the scope of the present disclosure. In some embodiments, the first material may be deposited in a pattern that complies with the specification and the second material may be coarsely deposited on top of and in-between the deposited first material. In these embodiments, subtractive manufacturing may be employed to bring the second material into compliance (or substantial compliance) with the specification for the layer. In other embodiments, the subtractive manufacturing acts may only be performed in response to the detection of a defect (e.g., an air bubble, a void, a breakage, and/or an electrical short) in the deposited material. In these embodiments, defects in the deposited material may be detected using one or more sensors and corrected using subtractive manufacturing techniques alone or in combination with additive manufacturing techniques.

The inventors have also appreciated that conventional additive manufacturing devices and conventional subtractive manufacturing devices are ill-suited to perform hybrid additive and subtractive manufacturing. Additive manufacturing devices, for example, typically do not have any capability to remove the debris generated from subtractive manufacturing. Such debris may remain on a top surface of the object and contaminate subsequently formed layers. Subtractive manufacturing devices typically do not include any material depositing equipment or even any mechanism that may be readily employed to deposit a material.

The inventors have also conceived and develop new machines to use the hybrid additive and subtractive manufacturing techniques disclosed herein to manufacture objects. In some embodiments, the machine may include a spindle that is configured to operate both material deposition tools to deposit multiple materials and cutting tools (e.g., milling tools, drilling tools, grinding tools, sanding tools, and/or laser etching tools). The spindle may operate the cutting tools by rotating a shaft onto which a cutting tool is mounted and/or providing power to the cutting tool via a slip ring assembly. The spindle may operate material deposition tools by providing a pressurized gas (e.g., compressed air) to the material deposition tool. For example, the material deposition tools may include a reservoir to hold a material to be deposited and the spindle may provide the pressurized gas to the material deposition tool to deposit the material through a nozzle of the material deposition tool. The machine may include a gas control device (e.g., a pressure regulator or gas compressor) and operate the gas control device to control the pressure of the pressurized gas provided to the material deposition tool. The machine may adjust the pressure to account for different material viscosities and/or different desired deposition rates. Thereby, the machine may accurately deposit a variety of different materials at different speeds to form an object.

Accordingly, some aspects of the present disclosure relate to a system designed to perform hybrid additive and subtractive manufacturing techniques to manufacture an object. The system may include a material deposition tool configured to receive a compressed gas and deposit a material using the received compressed gas. For example, the material deposition tool may include a reservoir to hold a material and a port to receive a compressed gas (e.g., compressed air). The pressure of the received compressed gas may determine a rate at which material is dispensed from the material deposition tool. The system may control the pressure, and thereby the deposition rate, via a gas control device (e.g., a pressure regulator and/or a gas compressor). For example, the system may receive a compressed gas at a constant pressure at a compressed gas inlet port and adjust the pressure of the compressed gas provided to the material deposition tool using a pressure regulator. In another example, the system may include an on-board gas compressor and control the pressure of the gas by controlling the gas compressor. The particular pressure level may be set by a controller communicatively coupled to the gas control device. The controller may adjust the pressure based on, for example, a viscosity of the material to be deposited and/or a desired deposition rate of the material.

The compressed gas may be provided to the material deposition tool via a spindle onto which the material deposition tool may be removably coupled. For example, the spindle may provide the compressed gas to a port in the material deposition tool to apply pressure to material in a reservoir of the material deposition tool and, thereby, force the material out of a nozzle. The spindle may be configured to operate tools other than the material deposition tool. For example, the spindle may be configured to receive a cutting tool and operate the cutting tool by rotating the cutting tool at a given speed (e.g., 65,000 revolutions per minute).

The machine may include a build platform disposed below the spindle onto which an object may be constructed. The build platform may be coupled to the spindle by a gantry system that is configured to move the spindle relative to the build platform. For example, the gantry system may move the spindle in a plurality of directions that are perpendicular to each other.

It should be appreciated that various alterations may be made to the machine without departing from the scope of the present disclosure. In some embodiments, the material deposition tool may be operated without employing a compressed gas. For example, the material deposition tool may include a motor integrated into the material deposition tool that rotates an auger to force material through a nozzle of the material deposition tool. In another example, the material deposition tool may include a port to receive a material to be deposited and the spindle may operate the material deposition tool by forcing material into the port. In yet another example, the material deposition tool may include a plunger coupled to a threaded shaft that passes through a threaded collar with a fixed location. In this example, the spindle may operate the material deposition tool by rotating the shaft to push the plunger forward and, thereby, deposit a material.

It should be appreciated that the embodiments described herein may be implemented in any of numerous ways. Examples of specific implementations are provided below for illustrative purposes only. It should be appreciated that these embodiments and the features/capabilities provided may be used individually, all together, or in any combination of two or more, as aspects of the technology described herein are not limited in this respect.

As discussed above, objects may be manufactured more rapidly by coarsely depositing material in a layer and subsequently removing some of the deposited material to bring the deposited material closer into compliance (or in full compliance) with the specification for the layer. Such processes may be readily applied to create any of a variety of objects including, for example, PCBs. PCBs typically mechanically support and electronically connect electronic components using various conductive features (e.g., conductive channels or conductive pads) integrated into a non-conductive substrate. For example, a PCB may include conductive pads onto which electronic components may be electrically coupled and conductive channels that electrically couple the conductive pads.

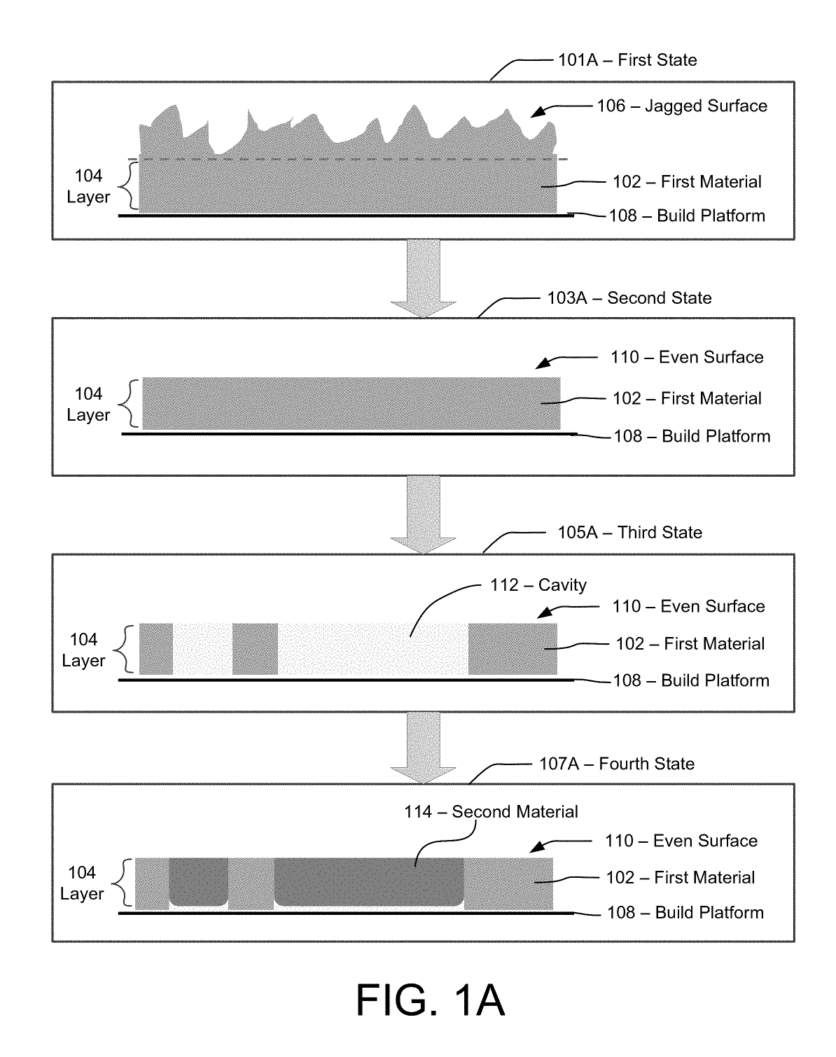

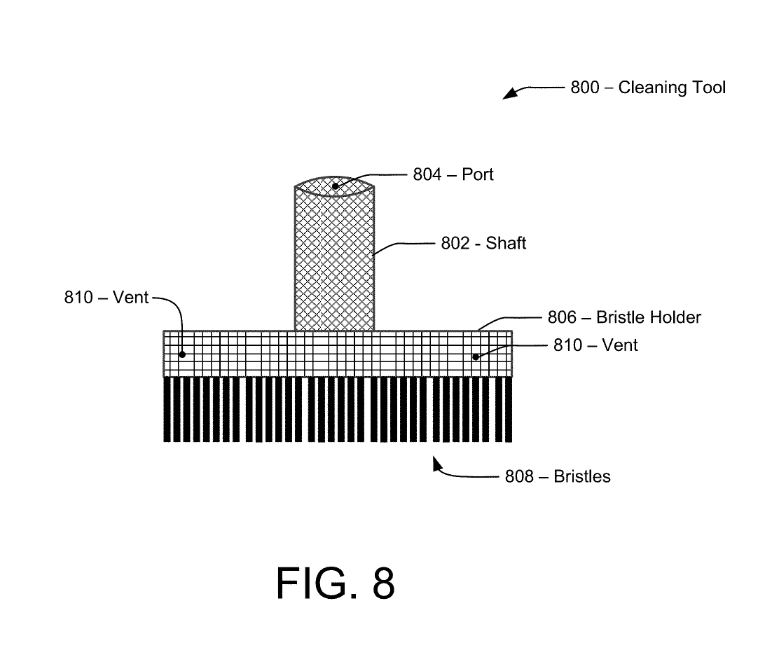

For illustration, FIG. 1A shows an example state diagram of a layer 104 of a PCB being formed on a build platform 108 in four states 101A, 103A, 105A, and 107A during a hybrid additive and subtractive manufacturing process (e.g., process 900 described below with reference to FIG. 9). As shown in FIG. 1A, the layer 104 includes a first material 102 that may form the non-conductive substrate of the final PCB and a second material 114 that may form the conductive features in the final PCB. The first material 102 may be a polymeric material such as a thermosetting matrix material (e.g., an epoxy resin, an acrylic resin, and/or a cyanate ester resin) or a thermoplastic (e.g., a polycarbonate, a polyetherimide, a polyether ether ketone, a polytetrafluoroethylene (PTFE), acrylonitrile butadiene styrene (ABS), a polyurethane, a polypropylene, a polystyrene, a nylon, a kapton, a polyamide, and/or a polyimide), a ceramic material, a fiber reinforced laminate material, and/or a semiconductor material. The second material 114 may be a conductive material that comprises a metallic material such as a conductive ink comprising conductive particles (e.g., silver polygons and nanorods, gold nanorods, silvercoated copper particles, silver-coated copper flakes, silvercoated copper rods, tin particles, nickel particles, and/or aluminum particles) dispersed in a solvent. The solvent may be selected to promote maximum surface area coverage that in turn promotes formation of a strong bond between the conductive ink and the first material 102. It should be appreciated that the layer 104 of the PCB may comprise more than the first and second materials 102 and 114, respectively. For example, the PCB may comprise dielectric materials, structural support materials, and magnetic materials.

In the first state 101A, the first material 102 has been coarsely deposited onto the build platform 108. The first material 102 may be, for example, a thermosetting matrix material that has been deposited onto the build platform 108 via DIW using a large nozzle (e.g., a ribbon nozzle or a circular nozzle with a diameter of between 4 mm and 9 mm) and cured (e.g., using an ultraviolet (UV) light source, an IR light source, a microwave source, an electron beam source, and/or a heat source). As shown, the first material 102 in the first state 101A is not in compliance with the specification for the layer. For example, the first deposited material is thicker than the desired height of the layer 104, has a jagged top surface 106, and omits all of the cavities for the second material 114 to be deposited into.

In the second state 103A, the jagged surface 106 of the first material 102 has been removed to form an even surface 110. Further, the thickness of the first material 102 has been reduced to be closer to (or in compliance with) the specified thickness for the layer 104. The top surface of the first material 102 may have been smoothed by subtractive manufacturing. For example, a facing tool may have been employed to smooth the jagged surface 106 of the first material 102. The first material 102 in the second state 103A, however, still does not include any cavities for the introduction of the second material 114.

In the third state 105A, cavities 112 have been formed in the first material 102 for the subsequent deposition of the second material 114. The cavities 112 may have been formed by subtractive manufacturing. For example, the cavities 112 may have been formed by a milling tool (e.g., an end mill with a diameter of between 25 micrometers (μm) and 500 μm spinning at 65,000 revolutions per minute (RPM)). The debris generated from the milling of the cavities may be removed using various cleaning tools. For example, a compressed gas may be employed to blow away the debris. Alternatively (or additionally), a brush may be employed to move the debris off of the first material 102 and/or out of the cavities 112.

In the fourth state 107A, the cavities 112 have been filled with the second material 114 to complete formation of the layer 104. The second material 114 may be, for example, deposited using DIW, a spray gun, a microjet dispenser, a microjet dispenser, evaporation, physical vapor deposition, electroplating, and/or a material spray. The second material 114 may be cured after deposition (e.g., using a ultraviolet (UV) light source, an IR light source, a microwave source, an electron beam source, and/or a heat source). The cavities 112 may have been filed with the second material 114 by, for example, directly depositing the second material 114 into the cavities 112 using a small nozzle (e.g., a nozzle with a diameter of 350 μm). In another example, the cavities 112 may have been filled by depositing the second material 114 on top of the first material 102 and forcing the second material 114 into the cavities 112 using a squeegee. In this example, the top surface of the first and second materials 102 and 114, respectively, may be faced to remove any excess second material 114 from the squeegeeing process.

In embodiments where the layer 104 comprises more than two materials, the second material 114 may be employed to fill a first portion of the cavities 112 and additional materials may be employed to fill a remaining portion of the cavities 112. For example, a first portion of the cavities 112 may be filled with a conductive material and the second portion of the cavities 112 may be filled with dielectric, structural support, and/or magnetic materials. In these embodiments, the cavities 112 for each material may be formed at different times. For example, the cavities 112 for the second material 114 may be formed and filled prior to the cavities for a third material being formed and filled.

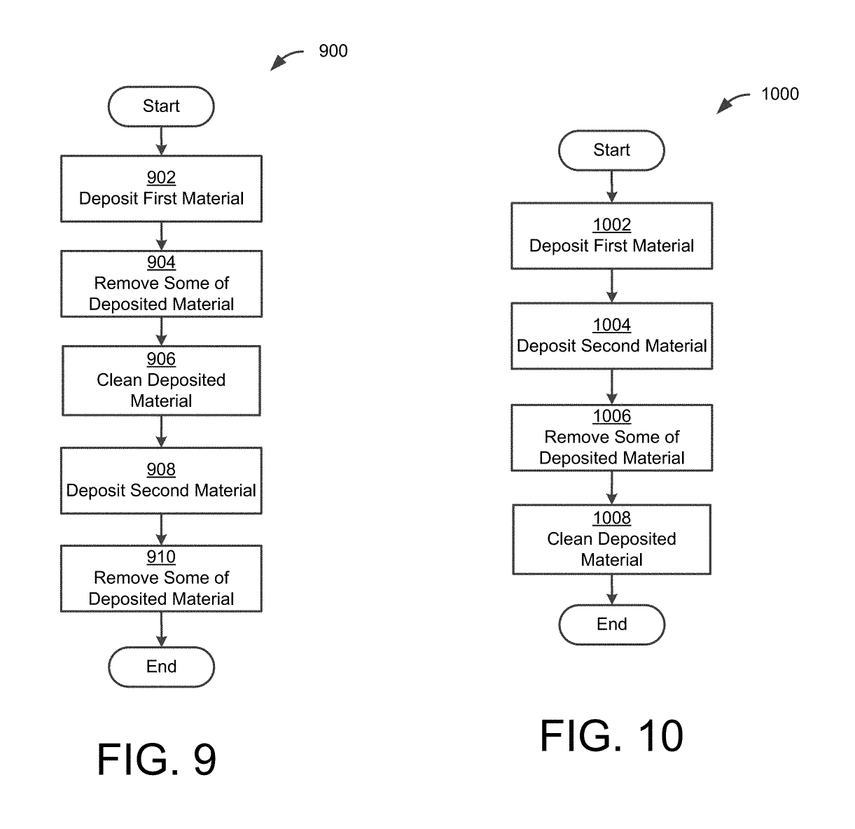

It should be appreciated that other combinations of additive and subtractive manufacturing techniques may be employed to manufacture a layer. For example, the second material 114 may be deposited first, the first material 102 may be coarsely deposited over the second material 114, and the deposited first and second materials 102 and 114, respectively, may be face milled to produce an even surface. FIG. 1B shows an example state diagram of a layer at three states 101B, 103B, and 103C during such hybrid additive and subtractive manufacturing process (e.g., process 1000 described below with reference to FIG. 10).

In the first state 101B, the second material 114 has been deposited in the layer 104. As shown, the second material 114 may be deposited in the pattern and/or width indicated in the specification for the layer 104. The second material 114 may, however, be thicker than the desired thickness of the layer 104. The second material 114 may be deposited via, for example, DIW using a small nozzle (e.g., a nozzle with a diameter of 350 μm). The second material 114 may be cured after deposition (e.g., using a UV light source, an IR light source, a microwave source, an electron beam source, and/or a heat source).

In embodiments where the layer 104 comprises more than two materials, additional materials may be deposited in the layer 104 alongside the second material 114 before being covered by the first material 102. For example, a dielectric, structural support, and/or magnetic material may be deposited on the build platform 108.

In the second state 103B, the first material 102 has been coarsely deposited over and between the second material 114. The first material 102 may be coarsely deposited onto the build platform 108 via, for example, DIW using a large diameter nozzle (e.g., 1 mm or larger in diameter) and cured (e.g., using a UV light source, an IR light source, a microwave source, an electron beam source, and/or a heat source). As shown, the first material 102 in the second state 101B is not in compliance with the specification for the layer 104. For example, the first material 102 is thicker than the desired height of the layer 104 and has a jagged top surface 106.

In the third state 105B, the top surface of the first and second materials 102 and 114, respectively, have been smoothed. Further, the thickness of the first material 102 has been reduced to be closer to (or in compliance with) the specified thickness for the layer. The top surface of the first material 102 may have been smoothed by subtractive manufacturing. For example, a facing tool may have been employed to smooth the jagged surface 106 of the first material 102.

Having described an example sequence of states of a layer of a PCB being manufactured, it should be appreciated that the PCB may comprise multiple layers and/or comprise additional materials (e.g., a dielectric material, a resistive material, a thermally conductive material, a dissolvable support material, and/or a magnetic material). Thereby, the sequence of states described above may be different for the formation of other layers. For example, some of the layers may only include a single material (e.g., the first material 104) and don't require the deposition of another material.

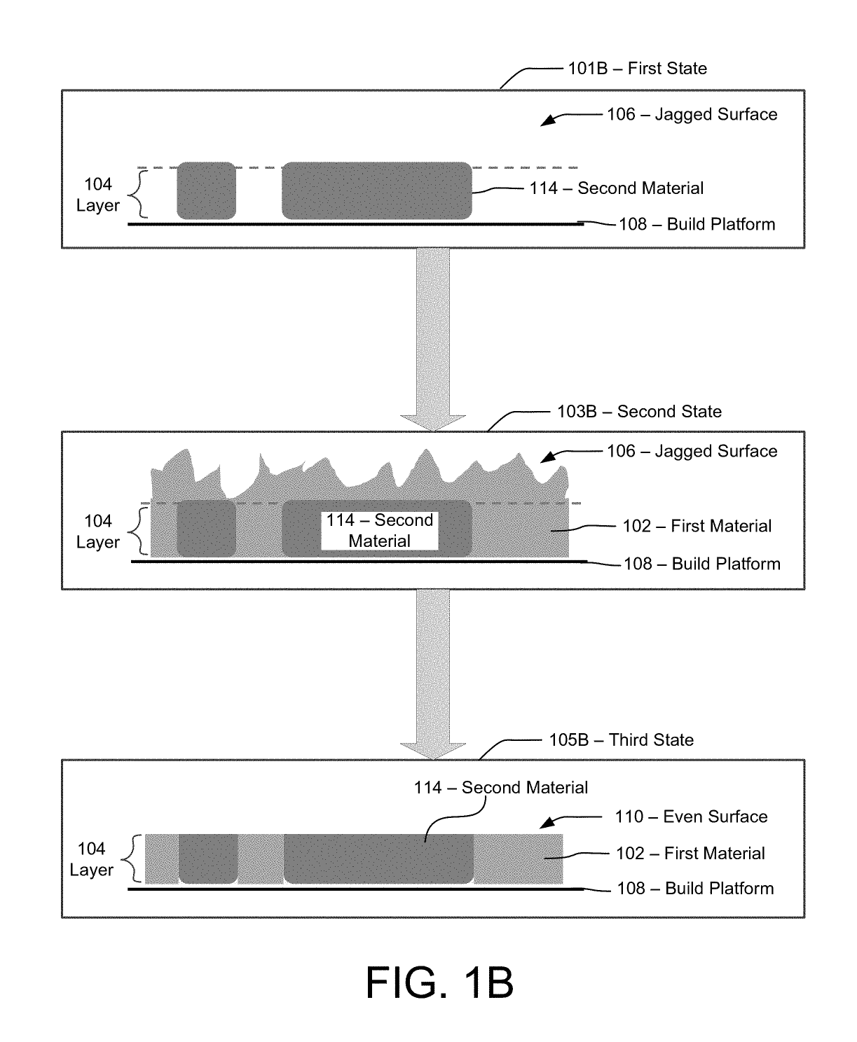

An example machine that may be employed to perform the hybrid additive and subtractive manufacturing techniques disclosed herein is shown in FIG. 2 by machine 200. As shown in FIG. 2, the machine 200 includes a build platform 202 coupled to a spindle 208 by a gantry system 204 that may be configured to move the spindle 208 relative to the build platform 202. The spindle 208 may operate a tool 206 mounted to the spindle 208 via a tool holder 210. A material storage compartment 218 may provide material to the tool 206 and/or tool holder 210 via a material line 220. Additionally (or alternatively), a gas control device 214 may provide a compressed gas to the tool 206 and/or tool holder 210 via a gas line 216. The gantry system 204, spindle 208, and/or the gas control device 214 may receive control signals from and be communicatively coupled to a controller 212. The machine 200 may store a plurality of tools including both cutting tools and material deposition tools in a tool storage compartment 222 that is coupled to the spindle 208 and/or the gantry system 204. The machine 200 may be configured to perform both additive and subtractive manufacturing by selecting tools from the tool storage compartment 222 and mounting the selected tools to the spindle 208 (e.g., via a tool changer). Thereby, the machine 200 may attach a material deposition tool to the spindle 208 to deposit a material, swap the material deposition tool for a cutting tool, and remove some of the deposited material.

It should be appreciated that the tool holder 210 may be integrated with the tool 206 and does not need to be separate from the tool 206 as shown in FIG. 2. In some embodiments, the tool 206 may include the necessary components to directly couple to the spindle 208. For example, a top portion of the tool 206 that is to be inserted into the spindle 208 may include a machine taper that is compliant with one or more standards. Example machine taper standards include CAT30, CAT40, CAT50, BT30, BT40, and BT50.

The gas control device 214 may control a pressure of a compressed gas (e.g., air) and provide the compressed gas to the tool 206 and/or the tool holder 210. The gas control device 214 may include a controllable pressure regulator and/or a controllable gas compressor that is configured to adjust a pressure of compressed gas based on, for example, a control signal from the controller 212. The gas control device 214 may be coupled to the tool 206 and/or tool holder 210 in any of a variety of ways. In some embodiments, the gas control device 214 may provide a compressed gas to the spindle 208 via the gas line 216. In these embodiments, the spindle 208 may provide the received gas to the tool 206 and/or tool holder 210 via one or more ports. In other embodiments, the gas control device 214 may provide compressed gas to the tool holder 210 and/or the tool 206 directly. In these embodiments, the gas line 216 may be directly attached to one or more ports in the tool 206 and/or tool holder 210. The gas line 216 may be removably coupled to the tool 206 and/or tool holder 210 such that the tool 206 and/or tool holder 210 may be mounted and unmounted from the spindle 208 as needed.

The material storage compartment 218 may store material (e.g., a resin) to be deposited via the tool 206. Material from the material storage compartment 218 may be forced out of the material storage compartment 218 using, for example, compressed air from the gas control device 214. The material storage compartment 218 may provide material to the tool 206 and/or tool holder 210 in any of a variety of ways. In some embodiments, the material storage compartment 218 may provide material to the spindle 208 via the material line 220. In these embodiments, the spindle 208 may provide the material to the tool 206 and/or tool holder 210 via one or more ports. In other embodiments, the material storage compartment 218 may provide the material to the tool 206 and/or tool holder 210 directly. In these embodiments, the material line 220 may be directly attached to one or more ports in the tool 206 and/or tool holder 210. The material line 220 may be removably coupled to the tool 206 and/or tool holder 210 such that the tool 206 and/or tool holder 210 may be mounted and unmounted from the spindle 208 as needed.

The spindle 208 may be configured to operate the tool 206. The spindle 208 may operate the tool 206 by, for example, spinning the tool 206, providing a compressed gas to the tool 206, providing a material to the tool 206, and/or providing power to the tool 206. The particular method employed by the spindle 208 to operate the tool 206 may vary based on the particular tool 206 being operated.

In some embodiments, the spindle 208 may be configured to operate the tool 206 by rotation. The rotation of the spindle 208 may operate, for example, various cutting tools such as drilling tools and milling tools. In these embodiments, the spindle 208 may include one or more motors (e.g., electric motors) that rotate a shaft onto which the tool 206 and/or tool holder 210 may be mounted. The spindle 208 may control the rotation rate of the shaft based on control signals received from the controller 212. For example, the spindle 208 may rotate the shaft (and thereby the tool 206) anywhere between 0 and 65,000 RPM.

In some embodiments, the spindle 208 may be configured to operate the tool 206 by providing compressed gas to the tool 206. The compressed gas from the spindle 208 may operate various material deposition tools, cleaning tools, and/or cutting tools. Material deposition tools may use the compressed gas to, for example, force material through a nozzle onto the build platform 202 and/or an object being manufactured. Cleaning tools may use the compressed gas to remove debris from the build platform 202 and/or an object being manufactured. Cutting tools may use the compressed gas to clear debris during cutting and/or use the compressed gas to rotate the cutting tool. The spindle 208 may receive the compressed gas from the gas line 216 and route the gas to a port in the tool 206 and/or tool holder 210. For example, the tool holder 210 may include a pull stud bolt that is affixed to an end of the tool holder 210 that is inserted into the spindle 208. In this example, the pull stud bolt may include a port to receive the compressed gas from the spindle 208 and the tool holder 210 may route the compressed gas to the tool 206.

In some embodiments, the spindle 208 may be configured to operate the tool 206 by providing power to the tool 206. The power received by the tool 206 may be employed to operate various electronic devices within the tool such as electric motors and curing elements (e.g., a UV source, an infrared (IR) source, an electronic beam (EB) source, and/or a heat source). The spindle 208 may provide power to the tool 206 in any of a variety of ways. In some examples, a slip ring assembly may be employed to provide power to the tool 206 while still allowing the tool 206 to freely rotate. The slip ring assembly may include a slip ring attached to the tool 206 and/or the tool holder 210 that is electrically coupled to one or more brushes attached to the spindle 208.

In some embodiments, the spindle 208 may be configured to operate the tool 206 by providing material to the tool 206. The material from the spindle 208 may operate material deposition tools configured to deposit material in any of a variety of ways (e.g., DIW, thermal spray, spray gun, etc.). For example, a material deposition tool may include a port to receive a material and be configured to deposit the received material through a nozzle. In this example, the spindle 208 may receive the material from the material line 220 and route the material to a port in the tool 206 and/or tool holder 210.

The gantry system 204 may be configured to move the spindle 208 in a plurality of directions relative to the build platform 202. The gantry system 204 may move the spindle 208, the build platform 202, and/or both the spindle 208 and the build platform 202. For example, the gantry system 204 may be configured to move the spindle 208 relative to the build platform 202 in the X-direction, Y-direction, and Z-direction by moving the spindle 208 in the Z-direction and moving the build platform 202 in the X-direction and the Y-direction. In another example, the location of the build platform 202 may be fixed and the gantry system 204 may be configured to move the spindle relative to the build platform 202 in the X-direction, Y-direction, and Z-direction.

The tool storage compartment 222 may store a plurality of tools 206 for use with the spindle 208. Example tools include material deposition tools to deposit material, cutting tools to remove some of the deposited material, curing tools to cure a deposited material, cleaning tools to clean a surface of an object being manufactured, and squeegee tools to force material into cavities in a deposited material. The tools 206 may be stored with (or without) tool holders 210. The tool storage compartment 222 may be implemented as, for example, a tool carousel comprising a carousel wheel mounted with a series of holders mounted to and distributed around the periphery of the carousel wheel to hold a plurality of tools 206.

In some embodiments, one or more tools 206 may be stored at a location separate from the tool storage compartment 222. The tools stored outside the tool storage compartment 222 may be bulky and/or oddly shaped tools that are not easily stored by the tool storage compartment 222. In these embodiments, the one or more tools may be located within reach of the spindle 208 such that the gantry system 204 may move the spindle 208 over the tool and mount the tool. For example, a curing tool (e.g., a hot press) may be located on the build platform 202 within reach of the spindle 208. In this example, the machine 200 may switch to the curing tool by unmounting a tool 206 from the spindle 208 (if one is mounted), moving the spindle 208 over to the curing tool, and operating the spindle 208 to mount the curing tool to the spindle 208.

The build platform 202 may include a build surface onto which an object may be constructed. The build surface may be, for example, a flat (or substantially flat) surface. The build platform 202 may include one or more mechanisms to increase adhesion between the build surface and the object being manufactured. For example, the build platform 202 may be a vacuum table including a vacuum pump that sucks air from a vacuum changer under the build surface to suck ambient air through holes in the build surface into the vacuum chamber. In another example, the build platform 202 may include one or more channels to allow the mounting of various clamps to the build platform 202. Alternatively (or additionally), the build platform 202 may include curing elements to facilitate curing of at least one material in an object being manufactured on the build platform 202. For example, the build platform 202 may include a heating element that heats an object in contact with a surface of the build platform 202 to cure at least some material in the object.

The controller 212 may be configured to control various components of the machine 200 to perform the hybrid additive and subtractive manufacturing processes disclosed herein. Example components that may be controlled by the controller 212 includes the spindle 208 (e.g., to control a speed of rotation of the spindle 208), the gantry system 204 (e.g., to control a position of the spindle 208 over the build platform 202), and the gas control device 214 (e.g., to control a pressure of the gas). The controller 212 may be implemented as, for example, a microcontroller or other suitable processing device.

The controller 212 may be communicatively coupled to at least one sensor 224 in the machine 200. In some embodiments, the sensor 224 may be used to detect defects (e.g., an air bubble, a void, a breakage, and/or an electrical short) in the deposited material. Thereby, the controller 212 may read the sensor 224 and direct the machine 200 to correct the defect by removing and/or adding material to the object being manufactured. Example sensors that may be used to detect defects in deposited material include a laser scanner, an imaging sensor, a force probe, and/or a voltage meter. In other embodiments, the sensor 224 may be used to determine a condition of the tool 206. For example, the sensor 224 may be configured to sense a force applied to rotate a shaft of the spindle 208 that may be indicative of whether a cutting tool is worn and/or broken. In yet other embodiments, the sensor 224 may be configured to measure an amount of material in the material storage compartment 218 and/or a pressure of the compressed gas from the gas control device 214.

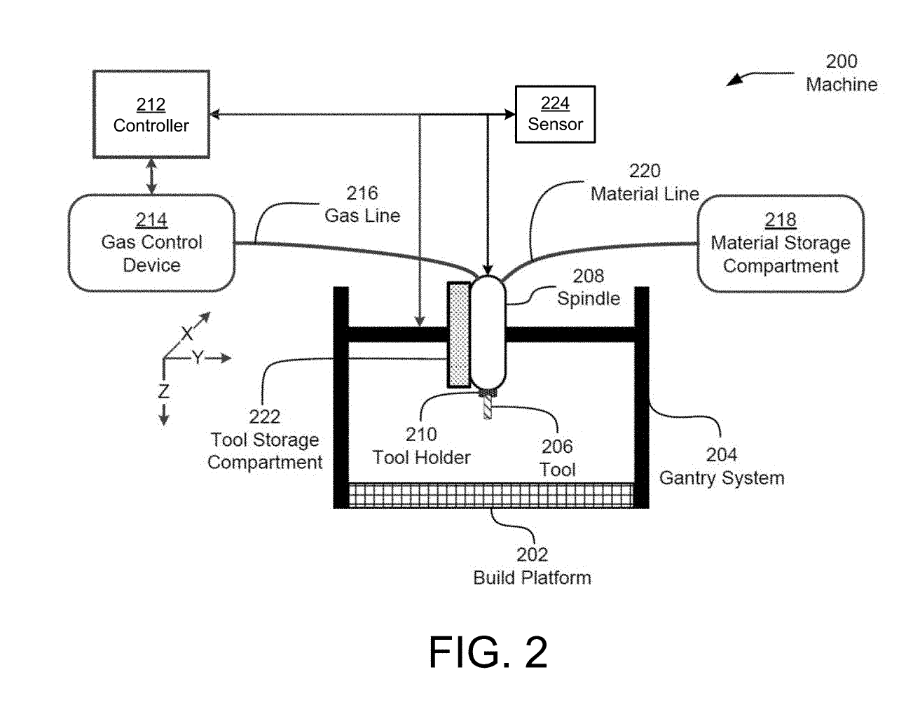

In some embodiments, the machine 200 may be at least partially enclosed by an enclosure to, for example, protect an operator from flying debris. An example enclosure is shown in FIG. 3 by enclosure 300. As shown, the enclosure 300 encloses the machine 200 and includes a door 302 with a handle 306 to provide an operator access to the machine 200. The door 302 includes a window 304 to allow an operator to see the machine without opening the door 302.

In some embodiments, the window 304 may be constructed from a material that blocks certain wavelengths of light. For example, the machine 200 may employ a curing element that emits UV light that may be harmful to humans. In this example, the window 304 may be constructed from a UV blocking material (e.g., a material that blocks at least 95% of UV light, a material that blocks at least 98% of UV light, or a material that blocks at least 99% of UV light) that is transparent (e.g., transmits at least 50% of visible light). The UV blocking material that is transparent may include, for example, a UV filtering acrylic.

It should be appreciated that the controller 212, sensor 224, gas control device 214, and/or material storage compartment 218 may be mounted in any of a variety of places on the machine 200 and/or the enclosure 300. For example, the material storage compartment 218 may be attached to a cover of the spindle 208. In another example, the sensor 224 may be mounted to an interior surface of the enclosure 300.

In some embodiments, one or more tools 206 may be attached to an interior surface of the enclosure 300 or a cover of the spindle 208 (instead of being mounted to the spindle 208) to, for example, reduce a number of tool changes required to create an object. For example, a curing tool including a curing element configured to cure a material deposited by a material deposition tool may be attached to a ceiling of the enclosure 300 and aimed downward at the building platform 202. In another example, the curing tool may be attached to the cover the spindle 208 and aimed downward at the building platform 202. In yet another example, a laser cutting tool configured to etch and/or cut an object on the build platform 202 may be attached to a ceiling of the enclosure 300.

It should be appreciated that various alterations may be made to the enclosure 300 without departing from the scope of the present disclosure. For example, enclosure may include one or more windows 304 separate from the window 304 in the door 302. Additionally (or alternatively), the enclosure 300 may include multiple doors 302 to ease operator access to the machine 200.

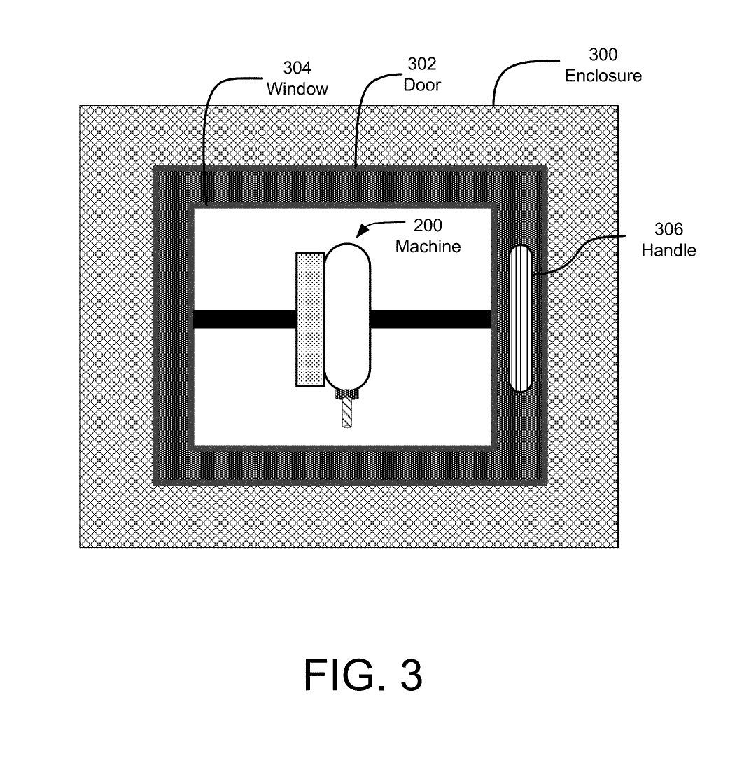

As discussed above, the machine 200 may swap tools between the tool storage compartment and the spindle 208. For example, the machine 200 may switch between a cutting tool and a material deposition tool. FIG. 4A shows an example tool changer 400 that may be constructed to swap tools between the tool storage compartment 222 and the spindle 208. As shown, the tool changer 400 includes a shaft 402 that is attached to an arm 404 that holds the tool 206 to be mounted to the spindle 208. The tool changer 400 may mount the tool 206 to the spindle 208 by grabbing the tool 206 with the arm 404 and rotating the shaft 402 attached to the arm 404 to move the tool 206 under the spindle 208. The tool changer 400 may then push the tool holder 210 upward into the spindle 208 and the spindle 208 may clamp onto the tool holder 210 as shown in FIG. 4B.

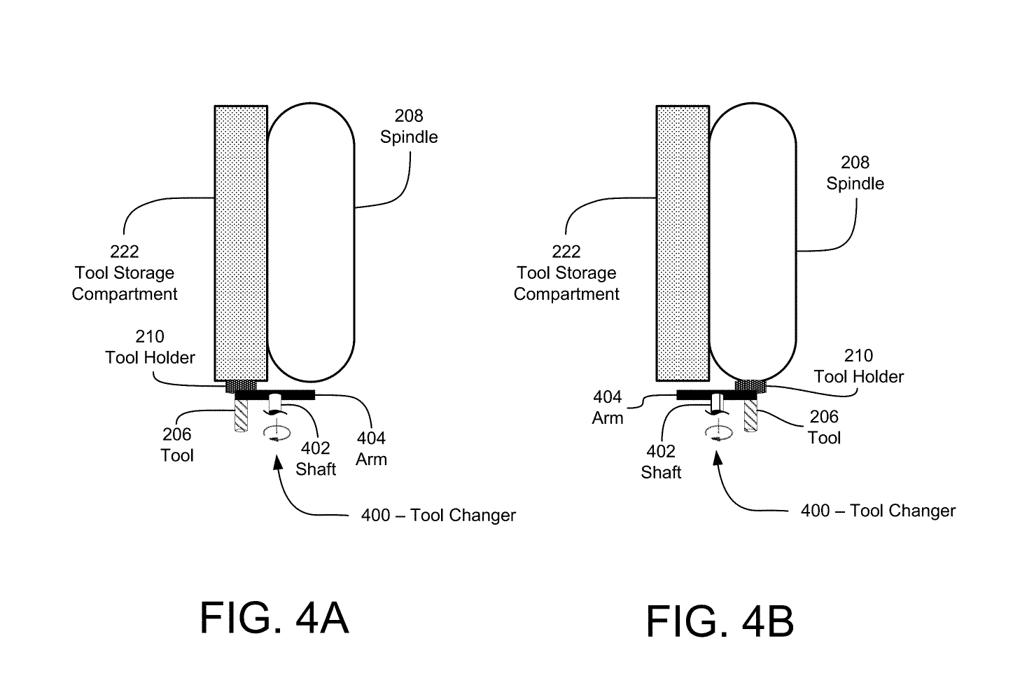

FIG. 5A shows an example material deposition tool 500A that may be configured to deposit a material. The material deposition tool 500A may be employed as, for example, tool 206 in FIG. 2. As shown, the material deposition tool 500A comprises a nozzle 502 through which a material is deposited and a reservoir 504 to hold the material. The reservoir 504 may be constructed to hold, for example, anywhere between 1 cubic centimeter (cc) and 946 cc of material. A cap 506 may be removably attached to the reservoir 504 to allow the reservoir 504 to be refilled. A shaft 508 with a port 510 may be coupled to the cap 506. The material deposition tool 500A may be operated by providing a compressed gas to the port 510 that may enter the reservoir 504 and, thereby, force material out of the nozzle 502 (e.g., in a stream or in a spray).

It should be appreciated that mechanisms other than pressure from a gas at the port 510 may be employed to deposit the material through the nozzle 502. In some embodiments, the material depositing 500A may include a motor that is configured to actuate an auger that pushes material out of the nozzle 502. The motor may receive power from, for example, the spindle 208 via a slip ring assembly. Thereby, the spindle 208 may operate the material deposition tool 500A by providing power to the motor via the slip ring assembly. Alternatively (or additionally), the motor may receive power directly from a power supply via a cable. In other embodiments, the material deposition tool 500A may include a plunger that is coupled to a threaded shaft that passes through a threaded collar with a fixed location. In this example, the plunger may be forced downward by rotating the threaded shaft through the threaded collar. Thereby, the spindle 208 may operate the material deposition tool 500A by rotating the threaded shaft.

In some embodiments, the material deposition tool may be configured to receive material from the material storage compartment 218 and, thereby, omit the reservoir 504. FIG. 5B shows such an example material deposition tool 500B. The material deposition tool 500B may be employed as, for example, tool 206 in FIG. 2. As shown, the material deposition tool 500B includes a shaft 514 that is coupled to a nozzle 502 and includes a port 512 to receive a material. The material deposition tool 500B may be operated by forcing material into the port 512 and, thereby, force material out of the nozzle 502. For example, the material line 220 may be coupled to the spindle 208 and the spindle 208 may provide the material to the material deposition tool 500B. In another example, the material deposition tool 500B may be directly coupled to the material line 220 and bypass the spindle 208.

The material deposition tools 500A-500B may be coupled to the machine 200 in any of a variety of ways. In some embodiments, the material deposition tools 500A-500B may be configured to removable couple (directly or indirectly) to the spindle 208 via the shafts 508 and 514, respectively. For example, the shafts 508 and 514 may be directly inserted into the spindle 208. In another example, the shafts 508 and 514 may be coupled to the tool holder 210 that is inserted into the spindle 208. In other embodiments, the material deposition tools 500A-500B may be coupled to a cover of the spindle 208 (instead of mounted to the spindle 208). In these embodiments, the material deposition tools 500A-500B may be positioned on the cover of the spindle 208 such that the bottom of the nozzle 502 is both below the bottom of the spindle 208 and above an end of the shortest tool. Thereby, the material deposition tools 500A-500B may not inhibit use of other tools and may be used by unmounting a tool from the spindle 208 (e.g., using the spindle 208 without a tool). The material deposition tools 500A-500B may be permanently coupled to a cover of the spindle 208 or removably coupled to the cover of the spindle 208 (e.g., to allow other material deposition tools 500A-500B to be operated with different size nozzles 502).

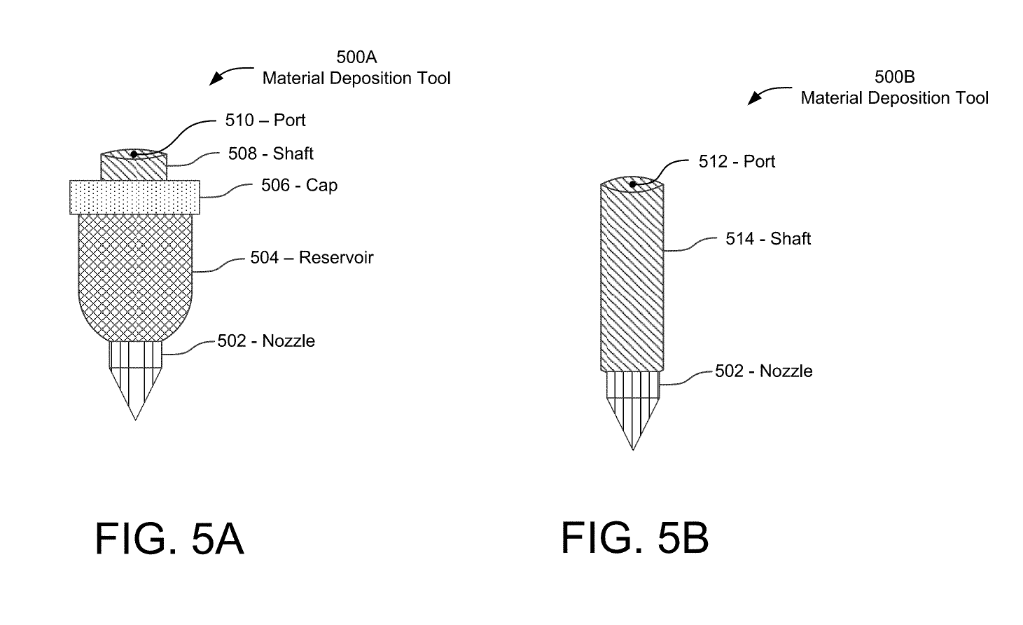

FIG. 6 shows an example squeegee tool 600 that may be configured to removably couple (directly or indirectly) to the spindle 208. The squeegee tool 600 may be employed as, for example, tool 206 in FIG. 2. The squeegee tool 600 may be configured to force material into cavities in a layer. As shown, the squeegee tool 600 includes a shaft 602 coupled to a blade holder 604 that is configured to hold a blade 606. The shaft 602 may allow the squeegee tool 600 to be removably coupled to the spindle 208. The blade holder 604 may hold the blade 606 in place. The blade 606 may be constructed from a flexible material, such as rubber.

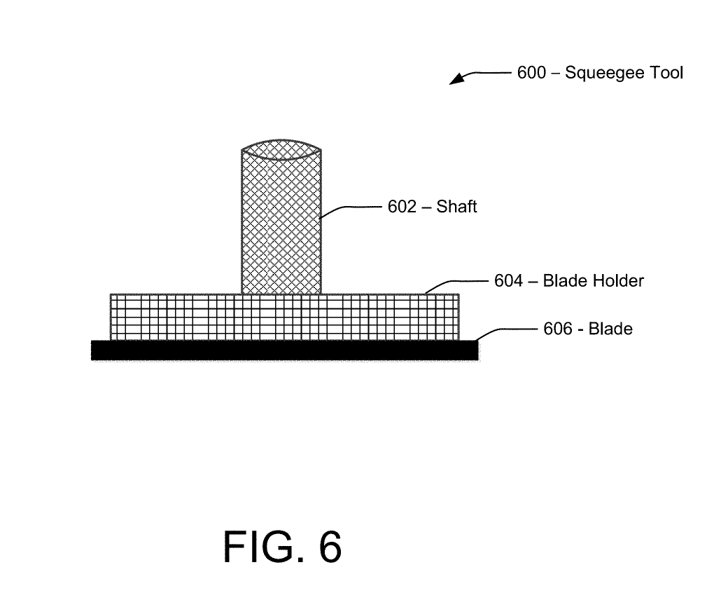

FIG. 7 shows an example curing tool 700 that may be configured to removably couple (directly or indirectly) to the spindle 208. The curing tool 700 may be employed as, for example, tool 206 in FIG. 2. The curing tool 700 may be configured to cure a layer of deposited material. As shown, the curing tool includes a shaft 702 with a slip ring 704 that is coupled to a curing element holder 706 configured to hold a curing element 708. The shaft 702 may allow the curing tool 700 to be removably coupled to the spindle 208 and/or a tool holder 210. The curing element 700 may receive power from the spindle 208 using the slip ring 704. Alternatively (or additionally), the curing element 700 may receive power directly from a power source via a cable. The curing element 708 may include any of variety of curing systems. For example, the curing element 708 may include a UV light source, an IR light source, a heat lamp, a hot press, a hot air gun, a flash lamp, a laser heater, a heated plate, and/or an electron beam source.

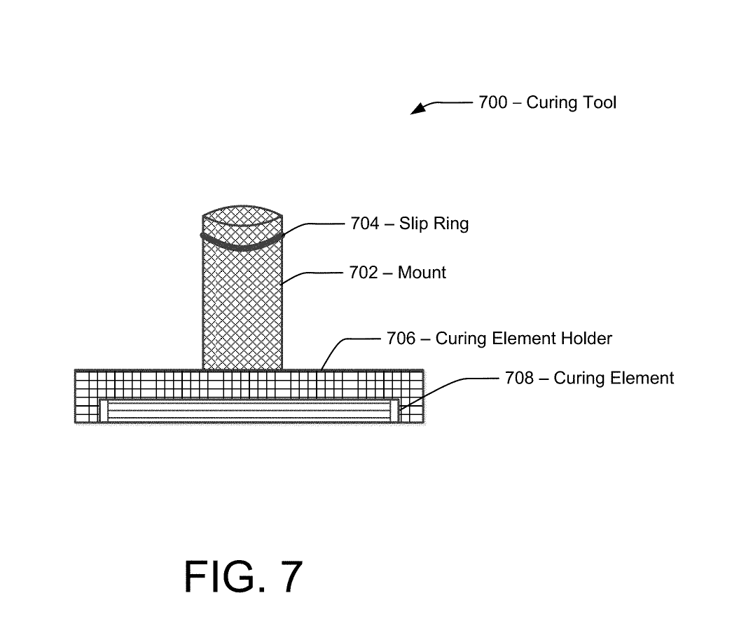

FIG. 8 shows an example cleaning tool 800 that may be configured to removably couple (directly or indirectly) to the spindle 208. The cleaning tool 800 may be employed as, for example, tool 206 in FIG. 2. The cleaning tool 800 may be used to clear debris from a deposited material. As shown, the cleaning tool 800 includes a shaft 802 with a port 804 that is coupled to a bristle holder 806 including vents 810 and being configured to hold bristles 808. The shaft 802 may allow the cleaning tool 800 to be removably coupled to the spindle 208. The port 804 may allow the cleaning tool 800 to receive a compressed gas that may be forced out to the vents 810 to blow away debris.

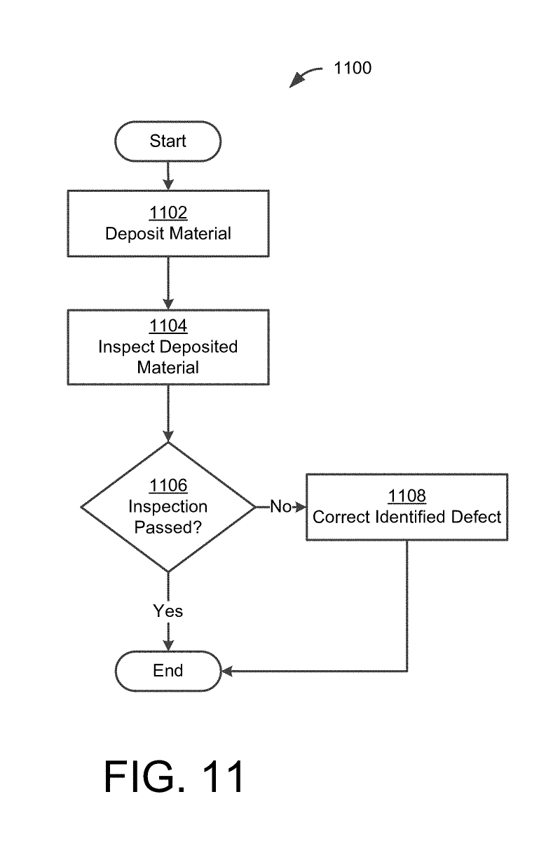

As discussed above, hybrid subtractive and additive manufacturing processes described herein may expedite the process of fabricating an object with multiple materials (e.g., a PCB). An example of such a process to manufacture at least a portion of a layer of an object that may be performed by, for example, machine 200 is illustrated by process 900 in FIG. 9. As shown, the process 900 includes an act 902 of depositing a first material, an act 904 of removing some of the deposited material, an act 906 of cleaning the deposited material, an act 908 of depositing a second material, and an act 910 of removing some of the deposited material. Each iteration of the process 900 may form a single layer of an object. Accordingly, the process 900 may be repeated as appropriate to form the requisite number of layers to manufacture an object. It should be appreciated that process 900 may not be used to manufacture every layer of an object and that other processes may be employed to form other layers in the same object (such as process 1000 in FIG. 10 and/or process 1100 in FIG. 11 described below).

In act 902, the first material is deposited as part of a layer using additive manufacturing. The first material may be coarsely deposited such that the first material is not in compliance with the specification for the layer. For example, the deposited first material may be too thick, have an uneven surface, and/or omit cavities for the second material to be deposited. Any of a variety of additive manufacturing techniques may be employed to deposit the first material such as DIW, SL, FDM, laser sintering, LOM, and material jetting. In some implementations, the first material may be a thermosetting matrix material (e.g., an epoxy resin) deposited using DIW with a large nozzle (e.g., a ribbon nozzle or a circular nozzle with a diameter of at least 1 mm). Depositing the thermosetting matrix material using a large diameter nozzle may allow the first material to be deposited quickly. Once the thermosetting matrix material has been deposited, the material may be cured using, for example, UV light. In other implementations, the first material may be deposited using thermal spray techniques. In these implementations, the first material may be, for example, a ceramic or a high temperature polymer (e.g., polyether ether ketone (PEEK)).

In some embodiments, the machine 200 may deposit the first material by selecting a first material deposition tool (e.g., material deposition tool 500A or 500B) from the tool storage compartment 222 and mounting the selected first material deposition tool to the spindle 208 using tool changer 400. Once the first material deposition tool is mounted to the spindle 208, the gantry system 204 in combination with the spindle 208 may be controlled (e.g., by controller 212) to appropriately position the spindle 208 over the build platform 202 and operate the first material deposition tool.

In act 904, some of the deposited first material may be removed using subtractive manufacturing. Some of the deposited first material may be removed to bring the deposited first material in compliance with (or closer to compliance with) the specification for the layer. For example, the deposited first material may omit cavities for the second material to be subsequently deposited and subtractive manufacturing may be employed to form these cavities. Any of a variety of subtractive manufacturing techniques may be employed to remove some of the deposited first material such as milling, drilling, grinding, sanding, and laser etching. In some implementations, the deposited first material may be faced to smooth a surface of the deposited first material and channels may be formed in the deposited first material. The channels may be formed using, for example, an end mill with a diameter of 500 μm spinning at 65,000 RPM. Alternatively (or additionally), the cavities may be formed using laser etching.

In some embodiments, the machine 200 may remove some of the deposited first material by selecting a cutting tool from the tool storage compartment 222 and mounting the selected cutting tool to the spindle 208 using tool changer 400. Once the cutting tool has been mounted to the spindle 208, the gantry system 204 in combination with the spindle 208 may be controlled (e.g., by controller 212) to appropriately position the spindle 208 over the build platform 202 and operate the cutting tool to remove some of the deposited first material. For example, the machine 200 may select a milling tool (e.g., an end mill) and employ the milling tool to create cavities in the first deposited material for subsequent deposition of a second material. Additionally (or alternatively), the machine 200 may select a facing tool (e.g., a face mill) and employ the facing tool to even a surface of the first deposited material.

The act 904 of removing some of the deposited material may generate debris that may contaminate subsequent layers if left to remain on the deposited first material. Accordingly, the deposited first material may be cleaned in act 906 to remove this debris. The deposited first material may be cleaned in any of variety of ways. For example, a compressed gas may be employed to blow debris off of the deposited first material. Additionally (or alternatively), a brush may be employed to move the debris off of the first deposited material.

In some embodiments, the machine 200 may clean the deposited first material by selecting a cleaning tool (e.g.., cleaning tool 800) from the tool storage compartment 222 and mounting the selected cleaning tool to the spindle 208 using tool changer 400. Once the cleaning tool has been mounted to the spindle 208, the gantry system 204 in combination with the spindle 208 may be controlled (e.g., by controller 212) to appropriately position the spindle 208 over the build platform 202 and operate the cleaning tool to remove the debris.

In act 908, a second material may be deposited in the same layer as the previously deposited first material using additive manufacturing. The second material may be deposited into, for example, cavities formed in the deposited first material in act 904. The second material may be deposited using the same (or different) additive manufacturing technique employed to deposit the first material. In some implementations, the second material may be conductive ink comprising conductive particles suspended in a solvent deposited using DIW. For example, the conductive ink may be directly deposited into the channels in the deposited first material. In another example, the conductive ink may be deposited on top of the first deposited material and forced into the channels using a squeegee. In other implementations, the second material may be deposited using thermal spray techniques. In these implementations, the second material may be, for example, a metal (e.g., silver, copper, and/or nickel).

In some embodiments, the machine 200 may deposit the second material by un-mounting the cleaning tool mounted in the spindle using tool changer 400 and mounting a second material deposition tool (e.g., material deposition tool 500A or 500B) in its place. Once the second material deposition tool has been mounted to the spindle 208, the gantry system 204 in combination with the spindle 208 may be controlled (e.g., by controller 212) to appropriately position the spindle 208 over the build platform 202 and operate the second material deposition tool. The machine 200 may, in some examples, directly deposit the second material into cavities into the deposited first material. In other examples, the machine 200 may deposit the second material on top of the deposited first material and force the second material into cavities in the deposited first material using a squeegee tool (e.g., squeegee tool 600).

In act 910, some of the deposited material may be removed using subtractive manufacturing. Some of the first and/or second deposited material may be removed to make a top surface of layer flat (or substantially flat). For example, the deposited first and second materials may be faced to prepare the layer for subsequent deposition of another layer. The same (or different) subtractive manufacturing techniques may be employed in act 904 relative to act 910. In some implementations, some of the deposited material may be removed by facing a top surface of the deposited first and second materials. For example, the top 10 μm-20 μm of the surface may be removed to remove any excess material from the act 908 of depositing the second material. In some embodiments, the machine 200 may remove some of the deposited material by selecting a cutting tool from the tool storage compartment 222 and mounting the selected cutting tool to the spindle 208 using tool changer 400. Once the cutting tool has been mounted to the spindle 208, the gantry system 204 in combination with the spindle 208 may be controlled (e.g., by controller 212) to appropriately position the spindle 208 over the build platform 202 and operate the cutting tool to remove some of the deposited first material. For example, the machine 200 may select a facing tool (e.g., a face mill) and employ the facing tool to even a surface of the first and second deposited material.

FIG. 10 shows another example process 1000 to manufacture at least a portion of a layer of an object (e.g., a PCB) that may be performed by, for example, machine 200 described above. Relative to the process 900 in FIG. 9, the first and second materials are deposited in succession prior to some of the deposited material being removed. As shown in FIG. 10, process 1000 includes an act 1002 of depositing a first material, an act 1004 of depositing a second material, an act 1006 of removing some of the deposited material, and an act 1008 of cleaning the deposited material.

In act 1002, the first material is deposited as part of a layer using additive manufacturing. The first material may be deposited in the specified pattern for the layer. However, the first material may be deposited at a different thickness (e.g., the deposited first material is thicker than a desired thickness for the layer). Any of a variety of additive manufacturing techniques may be employed to deposit the first material such as DIW, SL, FDM, laser sintering, LOM, and material jetting. In some implementations, the first material may be a conductive resin deposited using DIW with a small diameter nozzle (e.g., a nozzle with a diameter less than 1 mm).

In some embodiments, the machine 200 may deposit the first material by selecting a first material deposition tool (e.g., material deposition tool 500A or 500B) from the tool storage compartment 222 and mounting the selected first material deposition tool to the spindle 208 using tool changer 400. Once the first material deposition tool is mounted to the spindle 208, the gantry system 204 in combination with the spindle 208 may be controlled (e.g., by controller 212) to appropriately position the spindle 208 over the build platform 202 and operate the first material deposition tool.

In act 1004, the second material is deposited onto (and in-between) the first material using additive manufacturing. The second material may be coarsely deposited such that the second material is not in compliance with at least one specification for the layer. For example, the deposited second material may be too thick and/or have an uneven surface. The same (or different) additive manufacturing technique may be employed relative to act 1002. In some implementations, the second material may be a thermosetting matrix material (e.g., an epoxy resin) that is deposited via DIW using a large diameter nozzle (e.g., a ribbon nozzle or a circular nozzle with a diameter of at least 1 mm).

In some embodiments, the machine 200 may deposit the second material by selecting a second material deposition tool (e.g., material deposition tool 500A or 500B) from the tool storage compartment 222 and mounting the selected second material deposition tool to the spindle 208 using tool changer 400. Once the second material deposition tool is mounted to the spindle 208, the gantry system 204 in combination with the spindle 208 may be controlled (e.g., by controller 212) to appropriately position the spindle 208 over the build platform 202 and operate the second material deposition tool.

In act 1006, some deposited material may be removed using subtractive manufacturing. Some of the first and/or second deposited material may be removed to make a top surface of layer flat (or substantially flat). For example, the deposited first and second materials may be faced to prepare the layer for subsequent deposition of another layer.

In some embodiments, the machine 200 may remove some of the deposited material by selecting a cutting tool from the tool storage compartment 222 and mounting the selected cutting tool to the spindle 208 using tool changer 400. Once the cutting tool has been mounted to the spindle 208, the gantry system 204 in combination with the spindle 208 may be controlled (e.g., by controller 212) to appropriately position the spindle 208 over the build platform 202 and operate the cutting tool to remove some of the deposited first material. For example, the machine 200 may select a facing tool (e.g., a face mill) and employ the facing tool to even a surface of the first deposited material.

The act 1006 of removing some of the deposited material may generate debris that may contaminate subsequent layers if left to remain on the layer. Accordingly, the deposited first material may be cleaned in act 1008 to remove this debris. The deposited first material may be cleaned in any of variety of ways. For example, a compressed gas may be employed to blow debris off of the deposited first material. Additionally (or alternatively), a brush may be employed to move the debris off of the first deposited material.

In some embodiments, the machine 200 may clean the deposited first and second material by selecting a cleaning tool (e.g.., cleaning tool 800) from the tool storage compartment 222 and mounting the selected cleaning tool to the spindle 208 using tool changer 400. Once the cleaning tool has been mounted to the spindle 208, the gantry system 204 in combination with the spindle 208 may be controlled (e.g., by controller 212) to appropriately position the spindle 208 over the build platform 202 and operate the cleaning tool to remove the debris.

FIG. 11 shows another example process 1100 to manufacture at least a portion of a layer of an object (e.g., a PCB) that may be performed by, for example, machine 200 described above. Relative to the processes 900 and 1000 described above, subtractive manufacturing is performed when a defect (e.g., an air bubble, a void, a breakage, and/or an electrical short) is detected in a deposited material. Thereby, some (or all) of the deposited material may be removed to correct the defect and/or provide the machine another opportunity to deposit the material. Correcting defects in a layer while (or immediately after) the layer is being manufactured may advantageously reduce the scrap rate of the objects being manufactured. As shown in FIG. 11, process 1100 includes an act 1102 of depositing a material, an act 1104 of inspecting the deposited material, an act 1106 of determining whether the deposited material passed the inspection, and an act 1108 of correcting the identified defect.

In act 1102, a material is deposited in a layer using additive manufacturing. The material may be deposited using any of a variety of additive manufacturing techniques such as DIW, SL, FDM, laser sintering, LOM, and material jetting. The deposited material may form part of a layer of an object being manufactured. For example, the machine 200 may mount a material deposition tool (e.g., material deposition tool 500A or 500B) to the spindle 208 using tool changer 400. In this example, the gantry system 204 in combination with the spindle 208 may be controlled (e.g., by controller 212) to appropriately position the spindle 208 over the build platform 202 and operate the material deposition tool.

In act 1104, the deposited material may be inspected to determine whether the deposited material complied with a specification for the layer. Various sensors may be employed to inspect the deposited material such as a laser scanner, an imaging sensor, a force probe, and/or a voltage meter. For example, the machine 200 may employ a laser scanner as the sensor 224 and use the laser scanner to generate a profile of the deposited material. In this example, the generated profile of the deposited material may be compared with a specification for the layer to determine whether the deposited layer complies with the specification or contains defects.

In act 1106, a determination may be made as to whether the deposited material passed (or failed) the inspection performed in act 1104. If the deposited material passed the inspection, the process 1100 terminates. Otherwise, the process 1100 continues to act 1108 and corrects the identified defect using at least subtractive manufacturing. Any of a variety of subtractive manufacturing techniques may be employed such as milling, drilling, cutting, etching, grinding, sanding, planing, and turning. For example, the machine 200 may mount a milling tool to the spindle 208 and operate the milling tool to remove excess material in a layer. It should be appreciated that additive manufacturing techniques may be employed in combination with subtractive manufacturing techniques to correct a defect. For example, the machine 200 may detect that the deposited layer is unsalvageable using subtractive manufacturing techniques alone. In this example, the machine 200 may mount a facing tool to the spindle 208 and operate the facing tool to remove the deposited material in an entire layer. Thereby, the machine 200 may attempt to manufacture the layer again.

It should be appreciated that additional acts may be added to the processes 900, 1000 and/or 1100 without departing from the scope of the present disclosure. In some embodiments, an additional step of routing the object may be performed once all of the layers are printed to remove excess material from the sides of the object. For example, the object may be a PCB and the edges of the PCB may be routed to make the edges flat (or substantially flat). In other embodiments, an additional step of routing a layer may be performed after the formation of each object. In these embodiments, the routing may be employed to create, for example, a contoured 3D object.

In some embodiments, the first material and/or second material may require curing before any subtractive manufacturing techniques may be employed. In these embodiments, the processes may include curing acts immediately after deposition of a material (e.g., acts 902, 908, 1002, 1004, and/or 1102). The curing may be performed using, for example, a UV light source, an IR light source, a microwave source, an electron beam source, and/or a heat source.

In some embodiments, techniques may be employed to increase the adhesion between the first and second materials. For example, an adhesion promotor (e.g., a zinc adhesion promotor) may be applied in-between deposition of the first material and second material (e.g., just prior to act 908 in process 900 and/or just prior to act 1004 in process 1000). In another example, the first material may be a thermosetting material that is only partially cured prior to deposition of the second material. Thereby, the first material may still be tacky while the second material is being deposited. In this example, the first material may be completely cured after deposition of the second material.

In some embodiments, the hybrid manufacturing processes 900, 1000, and 1100 described above may be extended to manufacturing objects comprising more than two materials. For example, a fiber mat (e.g., a glass fiber mat) may be deposited prior to deposition of the first material and/or the second material (e.g., just prior to acts 902, 908, 1002, 1006, and/or 1102) to improve a rigidity of the resulting object. In this example, the fiber mat may be fused to a previous layer and/or the building surface by directly depositing the first and/or second material onto the fiber mat to impregnate it. Alternatively (or additionally), another material may be deposited onto the fiber mat to impregnate it and the first and/or second material may be deposited onto the impregnated fiber mat to bond to the impregnated mat. In another example, additional materials may be deposited with the first material in act 1002 (e.g., a dielectric material, a magnetic material, etc.) prior to the deposition a second material in act 1004 that covers the materials deposited in act 1002. In yet another example, additional materials may be deposited in act 908 to fill one or more cavities in the first material. For example, a first portion of the cavities may be filled with the second material and second portion of the cavities may be filled with a third material.

The processes described above are illustrative embodiments and are not intended to limit the scope of the present disclosure. The acts in the processes described above may be ordered in any suitable way. Accordingly, embodiments may be constructed in which acts are performed in an order different than illustrated, which may include performing some acts simultaneously, even though shown as sequential acts in illustrative embodiments.

Various aspects of the present disclosure may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Further, some actions are described as taken by a “user” or “operator.” It should be appreciated that a “user” or “operator” need not be a single individual, and that in some embodiments, actions attributable to a “user” may be performed by a team of individuals and/or an individual in combination with computer-assisted tools or other mechanisms.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately,” “about,” and “substantially” may be used to mean within ±20% of a target value in some embodiments, within ±10% of a target value in some embodiments, within ±5% of a target value in some embodiments, and yet within ±2% of a target value in some embodiments. The terms “approximately,” “about,” and “substantially” may include the target value.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having described above several aspects of at least one embodiment, it is to be appreciated various alterations, modifications, and improvements will readily occur to those skilled in the art. For example, the cooling techniques may be used in conjunction with other additive 3D printing techniques. Such alterations, modifications, and improvements are intended to be object of this disclosure. Accordingly, the foregoing description and drawings are by way of example only.

What is claimed is:

1. A method of manufacturing a three-dimensional (3D) object comprising a first material and a second material, the method comprising:
depositing the first material in a first layer via additive manufacturing;
removing at least some material in the first layer via subtractive manufacturing; and
after removing the at least some material in the first layer, depositing the second material in the first layer via additive manufacturing.

2. The method of claim 1, wherein removing the at least some material in the first layer comprises facing the deposited first material in the first layer.

3. The method of claim 1, wherein removing the at least some material in the first layer comprises forming at least one cavity in the deposited first material in the first layer.

4. The method of claim 3, wherein depositing the second material in the first layer comprises depositing the second material into the at least one cavity.

5. The method of claim 1, further comprising:
depositing the first material in a second layer that is on top of the first layer via additive manufacturing;
removing at least some material in the second layer via subtractive manufacturing; and
after removing the at least some material in the second layer, depositing the second material in the second layer via additive manufacturing.

6. The method of claim 1, further comprising:
depositing the second material in a second layer that is on top of the first layer via additive manufacturing;
depositing the first material in the second layer via additive manufacturing; and
after depositing the first and second materials in the second layer, removing at least some material in the second layer via subtractive manufacturing.

7. The method of claim 1, further comprising curing the deposited first material in the first layer before removing the at least some material in the first layer.

8. The method of claim 7, wherein curing the deposited first material comprises curing the deposited first material using at least one member selected from the group consisting of: ultraviolet (UV) light, infrared (IR) light, laser light, heat, and an electron beam.

9. The method of claim 1, further comprising cleaning the deposited first material after removing the at least some material in the first layer.

10. The method of claim 1, wherein additive manufacturing comprises at least one member selected from the group consisting of: direct ink writing (DIW), stereolithography (SL), fused deposition modeling (FDM), laser sintering, laminated object manufacturing (LOM), doctor blading, material spraying, and material jetting.

11. The method of claim 1, wherein subtractive manufacturing comprises at least one member selected from the group consisting of: milling, drilling, cutting, etching, grinding, sanding, planing, and turning.

12. A method of manufacturing a three-dimensional (3D) object comprising a first material and a second material, the method comprising:
depositing the first material in a first layer via additive manufacturing;
depositing the second material in the first layer using additive manufacturing; and
after depositing the first and second materials in the first layer, removing at least some material in the first layer via subtractive manufacturing.

13. The method of claim 12, wherein removing the at least some material in the first layer comprises removing at least some of the deposited first material and the deposited second material in the first layer.

14. The method of claim 12, wherein removing the at least some material in the first layer comprises facing the deposited first material and the deposited second material in the first layer.

15. The method of claim 12, further comprising:
depositing the second material in a second layer that is on top of the first layer via additive manufacturing;
depositing the first material in the second layer via additive manufacturing; and
after depositing the first and second materials in the second layer, removing at least some material in the second layer via subtractive manufacturing.

16. The method of claim 12, further comprising cleaning the deposited first and second materials after removing the at least some material in the first layer.

17. A method of manufacturing a printed circuit board (PCB), the method comprising:
depositing a thermosetting matrix material in a layer via additive manufacturing;
curing the thermosetting matrix material in the layer;
removing at least some material in the layer via subtractive manufacturing; and
after removing the at least some material in the layer, depositing a conductive material in the layer via additive manufacturing.

18. The method of claim 17, wherein depositing the thermosetting matrix material in the layer comprises depositing the thermosetting matrix material at least in part by direct ink writing or material spraying.

19. The method of claim 17, wherein removing the at least some material in the layer comprises forming at least one channel in the deposited thermosetting matrix material.

20. The method of claim 19, wherein depositing the conductive material in the layer comprises depositing the conductive material in the at least one channel.
